(19) United States
(12) Patent Application Publication
(10) Pub. No.: US 2025/0151484 A1
(43) Pub. Date: May 8, 2025

(54) MICRO LED MODULE FOR DISPLAY PIXELS, A DISPLAY DEVICE INCLUDING THE SAME, AND A MICRO LED REPAIR PROCESS FOR DISPLAY PIXELS

(71) Applicant: LG ELECTRONICS INC., Seoul (KR)

(72) Inventors: Naree KIM, Seoul (KR); Dongkyu LEE, Seoul (KR); Hongkey PARK, Seoul (KR); Sanggun LEE, Seoul (KR); Jeongsik CHOI, Seoul (KR)

(73) Assignee: LG ELECTRONICS INC., Seoul (KR)

(21) Appl. No.: 18/896,406

(22) Filed: Sep. 25, 2024

(30) Foreign Application Priority Data
Nov. 6, 2023 (KR) 10-2023-0151448

(51) Int. Cl. H01L 33/58; H01L 25/075; H01L 33/00; H01L 33/62

(52) U.S. Cl. CPC H10H 20/855; H10H 20/01; H10H 20/857; H01L 25/0753; H10H 20/0363; H10H 20/882

(57) ABSTRACT

A micro LED module according to an embodiment of the present invention may include a substrate, a solder resist layer disposed on the substrate, an electrode electrically connected to the substrate, a micro semiconductor light emitting device disposed on the solder resist layer electrically connected to the electrode, a first coating layer disposed on the solder resist layer, and a second coating layer disposed on the first coating layer, wherein the top surface of the first coating layer may be disposed at a height equal to or lower than the height of the top surface of the micro semiconductor light emitting device.

### CROSS-REFERENCE TO RELATED APPLICATIONS

Pursuant to 35 U.S.C. § 119, this application claims the benefit of earlier filing date and right of priority to Korean Application No(s). 10-2023-0151448, filed on Nov. 6, 2023, the contents of which are all incorporated by reference herein in its entirety.

### TECHNICAL FIELD

The present invention relates to a micro LED module for display pixels, a display device including the same, and a micro LED repair process for display pixels.

### BACKGROUND

Large-area display devices include a liquid crystal display (LCD), an OLED display, or a Micro-LED display.

Micro-LED display is a display that uses micro-LED, a semiconductor light emitting device with a diameter or cross-sectional area of 100 μm or less, as a display device.

Micro-LED displays use micro-LED, a semiconductor light-emitting device, as a display device, so they have excellent performance in many characteristics such as contrast ratio, response speed, color reproduction rate, viewing angle, brightness, resolution, life, luminous efficiency, and luminance.

In particular, the micro-LED display has the advantage of being able to freely adjust the size and resolution and to implement a flexible display because the screen may be separated and combined in a modular way. Micro-LED displays are not only applied to TVs but also to digital signage.

Digital signage is a display installed inside and outside a building using a digital information display (DID), and is a device that provides images or videos containing advertisements or various information.

Types of digital signage include outdoor digital signage and indoor digital signage.

Outdoor digital signage refers to digital signage installed on the exterior walls of buildings, electronic signboards, etc., or installed outside for outdoor cinema. Indoor digital signage refers to digital signage installed on the inner wall of a large shopping mall or in the form of a signboard.

In digital signage, a micro semiconductor light emitting diode (LED: Light Emitting Diode) may be used as a display device.

Micro LED is an ultra-small LED with a size of tens of microns. When used as a display, it has the advantages of high power efficiency, short response time, high brightness, and long lifespan compared to existing displays.

The pixels of the micro LED display panel require uniformity that is more stringent than the optical quality of existing LEDs.

Therefore, a stable process is required to prevent defective pixels from occurring during the manufacturing process, and if a defective pixel occurs, a process to repair the micro LED at the location where the defective pixel occurs is needed.

FIG. 1 shows a cross-sectional view of the micro LED module 10 of the internal technology, FIG. 2A shows the manufacturing process of the micro LED of the internal technology, and FIG. 2B shows the repair process of the micro LED of the internal technology.

Referring to FIGS. 1 to 2B, the micro LED module 10 in the internal technology includes a circuit board 110 on which the micro LED chip 140 is mounted, a photo solder resist (PSR) layer 120, an electrode 130 including first and second electrodes 131 and 132 disposed on the solder resist layer 120 and electrically connecting the micro LED chip 140, and silicone coating layer 150 including light scattering agent 151, a light scattering layer 160 disposed on the silicon coating layer 150, and a film layer 170 disposed on the light scattering layer 160.

In the process for manufacturing the micro LED module 10 in the internal technology, a jetting process is performed to cover the PSR layer 120, the electrode 130, and the micro LED chip 140, the jetted silicone coating layer 150 is subjected to a surface grinding process for planarization. Afterwards, the silicon OCA 160 and the film 170 are sequentially placed on the ground silicon coating layer 150 and then bonded by performing laminating fixation.

The micro LED repair process in internal technology involves removing the silicon OCA 160 and film layer 170 and grinding the silicon coating layer 150 to expose the micro LED chip 140. After replacing the micro LED chip 140 exposed through the grinding process, a process of jetting the silicon coating layer 150 is performed again. Afterwards, a grinding process is performed again to flatten the surface of the jetted silicon coating layer 150, and repair process is completed by sequentially placing the silicon OCA 160 and the film layer 170 on the ground silicon coating layer 150 and bonding them by performing laminating fixation.

However, when a repair process is performed to replace some defective pixels as in internal technology, there is a problem that requires a repetitive process of grinding the coating layer to replace a defective pixel, filling the coating layer again after replacing the defective pixel, and repeatedly performing a grinding process for flattening.

In addition, even if a defective pixel is replaced through a complex process, thickness deviation may occur due to the grinding process, etc. and PCB bending may occur due to thickness bias.

In addition, due to the removal of the entire silicon coating layer and then refilling, the boundary shape of the side part of the pixel may be visible, and there is a problem that defects such as weak points occur in some areas.

### SUMMARY

One of the technical objects of the present invention is to provide a micro LED module and a micro LED repair process that do not require a grinding process in the manufacturing and repair process of the micro LED module.

In addition, one of the technical objects of the embodiment is to provide a micro LED module and a micro LED repair process that facilitate repair of the micro LED module by easily removing the silicon coating layer from the interface of the micro LED chip.

The technical objects of the embodiments are not limited to those described in this item and include those that can be understood through the description of the invention.

Solutions for solving the technical object of the embodiments may include any one of the following.

A micro LED module for display pixels according to an embodiment may include a substrate, a solder resist layer disposed on the substrate, an electrode electrically connected to the substrate, a semiconductor light emitting device disposed on the solder resist layer when connected to the electrode, a first coating layer disposed on the solder resist layer, and a second coating layer disposed on the first coating layer, wherein a top surface of the first coating layer may be disposed at a height equal to or lower than the height of the top surface of the semiconductor light emitting device.

The height (h2) of the first coating layer may be 80% to 100% of the height (h1) of the semiconductor light emitting device. The first coating layer is formed concavely, and the height (h3) of the bottom surface of the first coating layer may be formed to be 15% to 75% of the height (h1) of the semiconductor light emitting device.

In addition, the embodiment may further include a gap formed between the semiconductor light emitting device and the solder resist layer.

In addition, the embodiment may further include a chip upper layer disposed on the second coating layer, wherein the chip upper layer may include a light scattering layer disposed on the second coating layer and containing a light scattering agent, and it may include a film layer disposed on the light scattering layer.

In addition, the first coating layer may have a refractive index of 1.48 to 1.60, the semiconductor light emitting device may have a refractive index of 1.7, and the second coating layer may have a refractive index of 1.41 to 1.47.

Further, a micro LED module for display pixels according to an embodiment may include a substrate, a solder resist layer disposed on the substrate, an electrode electrically connected to the substrate, a semiconductor light emitting device connected to the electrode and disposed on the solder resist layer, a first coating layer having a sloping surface disposed on the solder resist layer and a second coating layer disposed on the sloping surface of the first coating layer and the semiconductor light emitting device.

A top surface of the first coating layer may be disposed equal to or lower than a height of a top surface of the semiconductor light emitting device.

The sloping surface of the first coating layer may be concave.

A height of the bottom surface of the first coating layer may be formed to be 15% to 75% of the height of the semiconductor light emitting device.

Further the embodiment may include a gap between the micro semiconductor light emitting device and the solder resist layer.

Further the embodiment may include an upper chip layer disposed on the second coating layer, and the upper chip layer may include a light scattering layer disposed on the second coating layer, and a film layer disposed on the light scattering layer.

A refractive index of the first coating layer may be 1.48 to 1.60.

A refractive index of the semiconductor light emitting device may be 1.7.

A refractive index of the second coating layer may be 1.41 to 1.47.

In addition, the micro LED repair process according to the embodiment may include removing the upper layer of the semiconductor light emitting device, replacing the semiconductor light emitting device, forming a second-second coating layer, forming a second light scattering layer, and forming a second film layer.

Additionally, the step of removing the upper layer of the semiconductor light emitting device may include heating in an infrared oven.

Additionally, forming the second-second coating layer may include jetting the second-second coating layer and curing the second-second coating layer.

Additionally, the curing time of the second-second coating layer may be shorter than the curing time of the first coating layer.

According to the embodiment, a micro LED module and a micro LED repair process that do not require a separate grinding process in the manufacturing process and repair process may be provided.

In addition, according to the embodiment, an air gap may be formed at the bottom of the micro LED chip, making it resistant to thermal shock, and the micro LED chip can be easily removed during the repair process of the micro LED chip.

In addition, according to the example, no bubbles remain due to the coating layer even after the repair process, and visibility can be improved.

In addition, according to the example, the micro LED chip and the first and second coating layers each have different refractive indices, which has the effect of increasing light extraction efficiency.

Additionally, according to the embodiment, the flatness of the micro LED chip module can be improved.

The technical effects of the embodiments are not limited to those described in this item and include those that can be understood through the description of the invention.

### BRIEF DESCRIPTION OF THE DRAWINGS

The accompanying drawings, which are incorporated herein and form part of the specification, illustrate various, non-limiting embodiments of the present invention. In the drawings, like reference numbers indicate identical or functionally similar elements.

FIG. 1 shows a cross-sectional view of the micro LED module 10 of the internal technology.

FIG. 2A shows the manufacturing process of micro LED using internal technology.

FIG. 2B shows the repair process of micro LED of internal technology.

FIG. 3A is an exemplary diagram of a display device 1000 including a semiconductor light-emitting device for display pixels according to an embodiment.

FIG. 3B is a perspective view of one of a plurality of display modules 1200 included in the display device 1000 according to the embodiment.

FIG. 3C is a top view of one display panel 1210 included in the display panel 1210 according to the embodiment.

FIG. 4A is a cross-sectional view of the micro LED module 20 according to the embodiment of the present invention.

FIG. 4B is a cross-sectional view of the semiconductor light emitting device 240 shown in FIG. 4A.

FIG. 5 is a cross-sectional view of the micro LED module 30 according to a second embodiment of the present invention.

FIG. 6 is a diagram showing a process for manufacturing a micro LED module according to the embodiment of the present invention.

FIG. 7 is a diagram showing the repair process of a micro LED module according to the embodiment of the present invention.

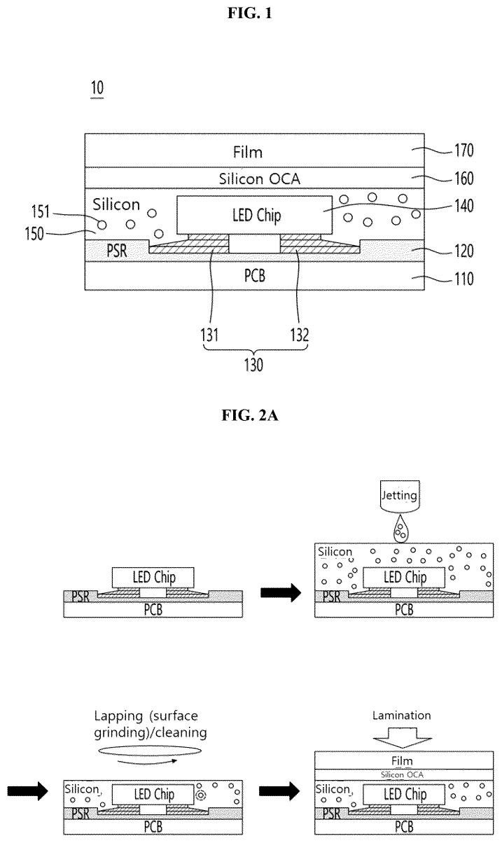

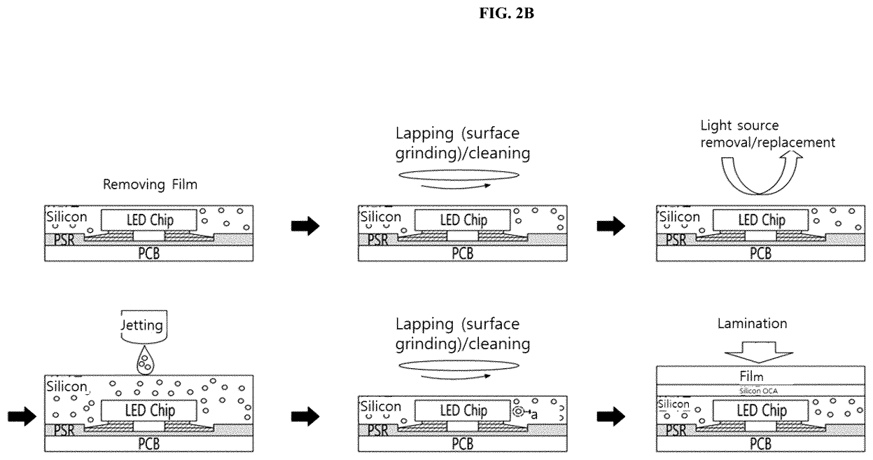

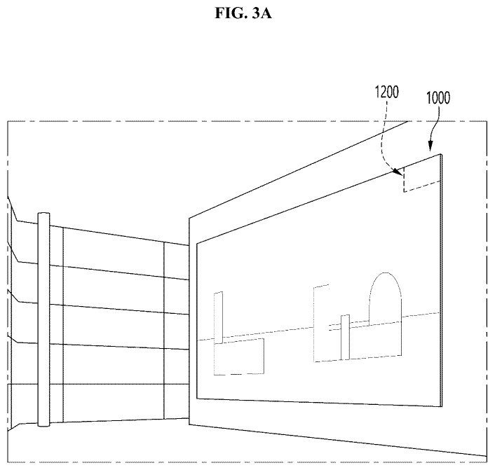

### DETAILED DESCRIPTION

Hereinafter, specific embodiments that can be implemented to solve the above problems will be described with reference to the attached drawings.

In the description of the embodiment, In the case where it is described as being formed “on or under” each configuration, on or under includes two elements that are in direct contact with each other or one or more other elements that are disposed (indirectly) between the two elements. Additionally, when expressed as “on or under,” it can include not only the upward direction but also the downward direction based on one configuration.

### Embodiment

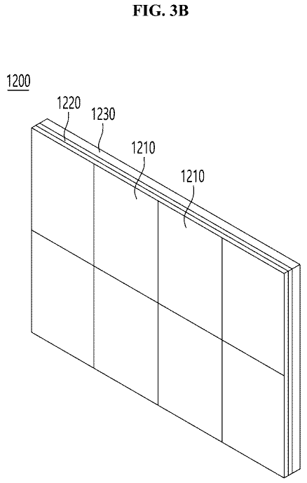

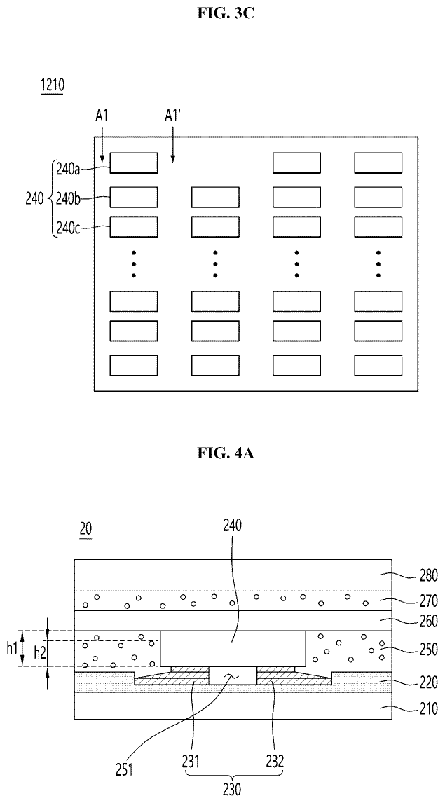

FIG. 3A is an exemplary diagram of a display device 1000 including a semiconductor light-emitting device for display pixels according to the embodiment. The display device 1000 according to the embodiment may include a plurality of assembled display modules 1200.

The display device 1000 of the embodiment may be applied to digital signage. For example, FIG. 3A is an example of indoor digital signage, but the display device 1000 of the embodiment may also be applied to outdoor digital signage.

FIG. 3B is a perspective view of one of the plurality of display modules 1200 included in the display device 1000 according to the embodiment.

The display panel 1200 shown in FIG. 3B may be mounted on each cabinet and assembled in a block manner to implement the display device 1000 of the embodiment.

The display module 1200 of the embodiment may include a plurality of display panels 1210 that output images, a module holder 1220 on which the display panel 1210 is placed, and a module cover 1230 disposed outside the module holder 1220.

The plurality of display panels 1210 may be arranged on the module holder 1220 in a grid form to form one display module 1200, and the individual display module 1200 may be assembled into a predetermined cabinet shape to implement the display device 1000 according to the embodiment. Display data may be transmitted wired or wirelessly to the assembled individual display module 1200.

FIG. 3C is a top view of one display panel 1210 included in the display panel 1210 according to the embodiment.

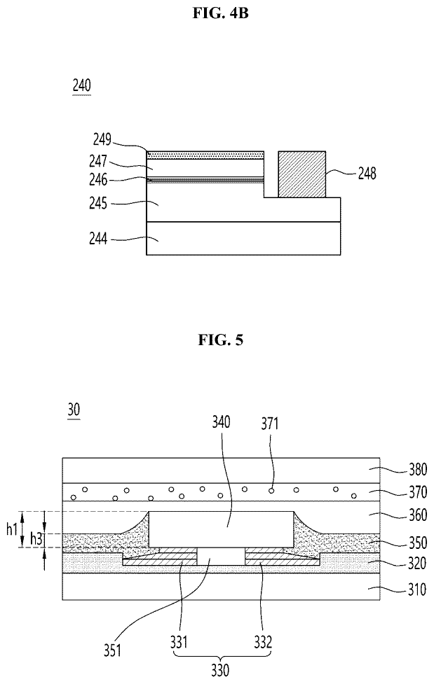

FIG. 4A is a cross-sectional view of the semiconductor light emitting device package taken along line A1-A1′ in the display panel 1210 according to the embodiment shown in FIG. 3C.

Referring to FIG. 3C, the display panel 1210 according to the embodiment may include a semiconductor light emitting device 240 for display pixels that implements each pixel.

For example, the semiconductor light-emitting device 240 for a display pixel according to the embodiment may include a first semiconductor light-emitting device 240a, a second semiconductor light-emitting device 240b, and a third semiconductor light-emitting device 240c, but it is not limited to this.

Each of the first to third semiconductor light emitting devices 240a, 240b, and 240c may be repeatedly arranged to form individual subpixels. For example, the first to third semiconductor light emitting devices 240a, 240b, and 240c may be red light emitting devices, green light emitting devices, and blue light emitting devices, respectively, but are not limited thereto.

The first to third semiconductor light emitting devices 240a, 240b, and 240c may have a size in micrometers μm. The micrometer μm size may mean that the width of at least one side of the light emitting device is several to hundreds of μm.

FIG. 4A is a cross-sectional view of the micro LED module 20 according to the embodiment of the present invention.

Specifically, FIG. 4A is a cross-sectional view of a semiconductor light emitting device package in which the adjacent first semiconductor light emitting device 240 shown in FIG. 3C is disposed on the wiring substrate 230.

The micro LED module 20 according to one embodiment may include a printed circuit board 210, a solder resist layer 220, an electrode 230 electrically connected to the solder resist layer 220, a micro LED chip 240 electrically connected to the electrode 230 and disposed on the solder resist layer 220, a first coating layer 250 disposed on the solder resist layer 220, a second coating layer 260 disposed on the first coating layer 250, a third coating layer 270 disposed on the second coating layer 260 and a film layer 280 disposed on the light scattering layer 270.

The printed circuit board 210 may be made of a conductive board or an insulating board. For example, the printed circuit board 210 may be formed of at least one of sapphire (Al₂O₃), SiC, Si, GaAs, GaN, ZnO, Si, GaP, InP, Ge, or Ga₂O₃.

The solder resist layer 220 may be disposed on the printed circuit board 210. The solder resist layer 220 may be a photo solder resist (PSR) layer, but is not limited thereto.

The solder resist layer 220 may protect the printed circuit board 220 and may function to prevent the solder bridge phenomenon.

The electrode 230 may include a first electrode 231 and a second electrode 232 respectively connected to the micro LED chip 240. The first electrode 231 and the second electrode 232 may be arranged to be spaced apart. The micro LED chip 240 and the printed circuit board 210 may be electrically connected through the electrode 230.

The micro LED chip 240 may be disposed on the solder resist layer 220 and may be electrically connected to the electrode 230.

FIG. 4B is a cross-sectional view showing the LED chip 240 of the embodiment in detail. Referring to FIG. 4B, the LED chip 240 may have a light emitting structure disposed on the substrate 244. The substrate 244 may be a growth substrate for growing a light emitting structure, and may be a sapphire substrate. The light emitting structure may include a first conductivity type semiconductor layer 245, an active layer 246, and a second conductivity type semiconductor layer 247 arranged sequentially.

The first conductivity type semiconductor layer 245 may be an n-type semiconductor layer, and the second conductivity type semiconductor layer 247 may be a p-type semiconductor layer, but are not limited thereto.

The LED chip 240 in the embodiment may include a first electrode 248 disposed on the exposed first conductivity type semiconductor layer 245 and a second electrode 249 disposed on the second conductivity type semiconductor layer 247. The LED chip 240 of the embodiment may be mounted on a wiring substrate using a flip chip method, but is not limited thereto. Accordingly, the upper surfaces of the first electrode 248 and the second electrode 249 may be positioned at the same height.

Referring again to FIG. 4A, a gap 251 may be formed by the micro LED chip 240, the electrode 231, and the solder resist layer 220. Since the first coating layer 250 does not fill the gap 251, it can be resistant to thermal shock (for example, −45° C. to 125° C., 300 cycles) caused by heat generation from the LED chip. In addition, when replacing the micro LED chip 240, the micro LED chip 240 functions to be easily removed from the first coating layer 250.

The first coating layer 250 may be disposed on the solder resist layer 220 and may be disposed to fix the side surface of the micro LED chip 240. The top surface of the first coating layer 250 may be formed in a flat structure.

The first coating layer 250 may include an epoxy- or silicone-based transparent material with adhesive strength. The first coating layer 250 may optionally include a carbon black material to improve the black feel.

The first coating layer 250 may be placed on the solder resist layer 220 through jetting and then may be cured. For example, the first coating layer 250 may be hardened at 100 to 116° C.

The first coating layer 250 may be formed to have a thickness of 50 μm to 250 μm. If the thickness of the first coating layer 250 is formed to be less than 50 μm, problems such as uneven thickness and impossibility of planarization may occur. Additionally, when the thickness of the first coating layer 250 exceeds 250 μm, increased side light may occur when the minimum thickness of the second coating layer is included.

The height h2 of the top surface of the first coating layer 250 based on the bottom surface of the micro LED chip 240 may be disposed to be lower than or equal to the height h1 of the micro LED chip 240. For example, the height h2 of the first coating layer 250 may be formed in the range of 80% to 100% of the height h1 of the micro LED chip 240.

If the height h2 of the first coating layer 250 is greater than the height h1 of the micro LED chip 240, it covers the upper surface of the micro LED chip 240, and problems may occur later during the micro LED chip replacement process.

With this structure, there is an advantage that a separate grinding process is not necessary when manufacturing the module of the micro LED chip.

Additionally, during the repair process of the micro LED chip, the second coating layer 260 may be easily separated from the first coating layer 250.

The second coating layer 260 may be arranged to cover both the top surface of the first coating layer 250 and the top surface of the micro LED chip 240.

The second coating layer 260 may include an epoxy- or silicone-based transparent material with adhesive strength.

The second coating layer 260 may be formed by disposing the second coating layer 260 on the second coating layer 250 by jetting and then curing it. For example, the second coating layer 260 may be hardened at 80 to 90° C.

The second coating layer 260 may be easily separated from the first coating layer 250 during the repair process of the micro LED chip.

The light scattering layer 270 may include a light scattering agent 271.

The light scattering layer 270 may include a silicon-based material with adhesive strength. For example, the light scattering layer 270 may include silicon OCA. The light scattering layer 270 may be formed to have a thickness of approximately 30 μm.

The film layer 280 may be disposed on the light scattering layer 270, and may be formed by selectively mixing a black material. The thickness of the film layer may be about 50 μm.

The refractive index of the light scattering layer and the film layer may be 1.41 to 1.46.

The refractive index of the second coating layer may be 1.41 to 1.47.

The refractive index of the first coating layer may be 1.48 to 1.60.

The refractive index of the micro LED chip may be 1.7.

If each layer has a different refractive index, the light extraction effect of the micro LED chip can increase.

Next, FIG. 5 is a cross-sectional view of the micro LED module 30 according to the second embodiment of the present invention.

The micro LED module 30 according to the second embodiment may include a printed circuit board 310, a solder resist layer 320 disposed on the printed circuit board 310, an electrode 330 electrically connected to the solder resist layer 320, a micro LED chip 340 electrically connected to the electrode 330 and disposed on the solder resist layer 320, and a first coating layer 350 disposed on the solder resist layer 320, a second coating layer 360 disposed on the first coating layer 350, a third coating layer 370 disposed on the second coating layer 360, and a film layer 380 disposed on the third coating layer 370.

The second embodiment may adopt the technical features of the embodiment previously described with reference to FIG. 4A, and the description will now focus on the main features of the second embodiment.

The first coating layer 350 according to the second embodiment may be jetted with a smaller volume than the first coating layer 250 according to one embodiment.

The first coating layer 350 according to the second embodiment may have a concave curved structure. The first coating layer 350 may be in contact with the side of the micro LED chip 340 and may be formed to be concave from the side of the micro LED chip 340.

The height h3 of the lowest point of the first coating layer 350 based on the bottom surface of the micro LED chip 340 may be formed within the range of 15% to 75% of the height of the micro LED chip 340.

Due to this structure, the contact area of the first coating layer 350 with the second coating layer 360 can increase, thereby increasing adhesion.

In addition, the side surface of the micro LED chip 340 may be exposed from the first coating layer 350, during a repair process for the micro LED chip, it may be easy to remove the micro LED chip 340 from the first coating layer 350.

In addition, since the coating liquid of the first coating layer 350 is jetted at a small volume, the coating liquid of the first coating layer 350 is not injected into the gap 351 between the solder resist layers 320.

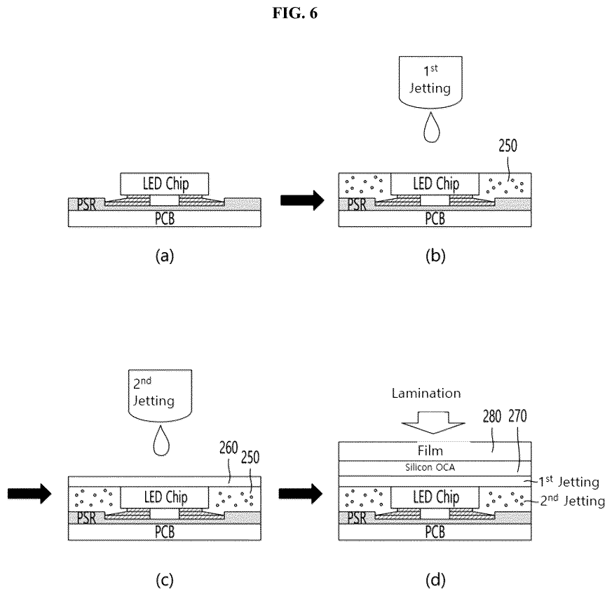

Next, FIG. 6 is a diagram showing a process for manufacturing a micro LED module according to the embodiment of the present invention.

Referring to FIG. 6, a process of forming the first coating layer 250 may be performed with the solder resist layer 220, the electrode 230, and the micro LED chip 240 disposed on the printed circuit board 210.

The process of forming the first coating layer 250 may include a first jetting process in which the first coating layer is jetted.

The process of forming the first coating layer 250 may be performed as a first curing process of curing the first coating layer at a temperature higher than the curing temperature. The first curing process may be carried out in a hot air oven at about 250 to 270° C. or more for 2 hours or more.

After the first coating layer 250 is formed, a process of forming the second coating layer 260 may be performed.

The process of forming the second coating layer 260 may include a secondary jetting process in which the second coating layer is jetted. The overall thickness deviation of the first coating layer 250 and the second coating layer 260 may be reduced by the secondary jetting process.

The process of forming the second coating layer 260 may include a second curing process to cure the second coating layer after the second jetting process.

The second curing process may be carried out in an infrared oven at about 80 to 100° C. or more for 10 minutes or more.

The second coating layer may maintain flat by quickly hardening without flowing on the surface of the first coating layer 250. The number of functional groups that cause hardening of the first coating layer may be less than the number of functional groups in the second coating layer.

When the second coating layer 260 is cured, a process of applying the light scattering layer 270 containing the light scattering agent 271 on the second coating layer 260 may be performed.

Afterwards, a laminating process may be performed after placing the film layer 280 on the light scattering layer 270.

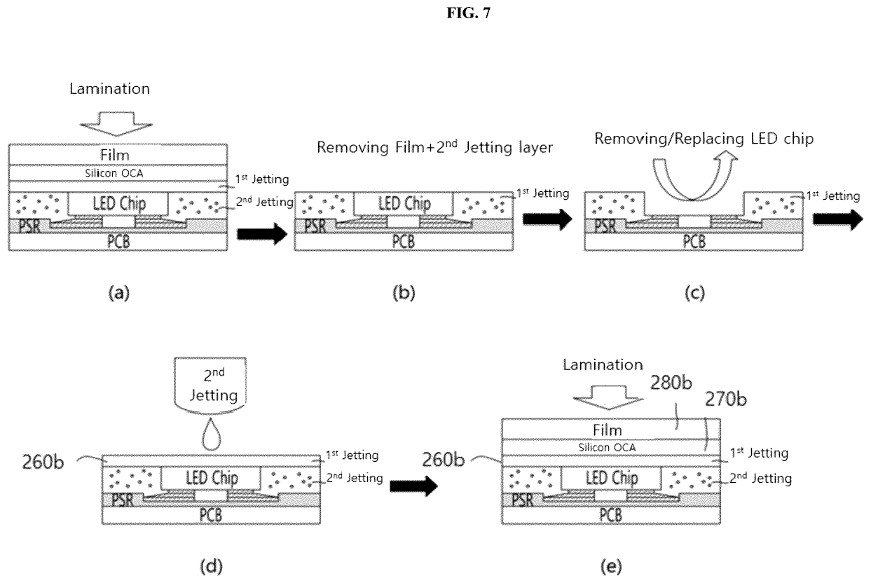

Next, FIG. 7 is a diagram showing the repair process of a micro LED module according to the embodiment of the present invention.

Referring to FIG. 7, a repair process may be performed to replace some of the damaged micro LED chips 240. Below, the embodiment according to the present invention will be described as an example, but a repair process may also be performed in the second embodiment through the same process.

First, a process of removing the film layer 280, the light scattering layer 270, and the second coating layer 260 may be performed. The film layer 280, the light scattering layer 270, and the second coating layer 260 may be referred to as the upper chip layer.

The process of removing the upper chip layer may be performed under process conditions of approximately 80 to 100° C. and 10 to 20 minutes. Under the above process conditions, the functional group bond between the second coating layer 260, the first coating layer 250, and the micro LED chip 240 may be weakened, so that the upper layer of the chip may be easily removed. The process of removing the upper chip layer has the technical effect of eliminating the need for a separate grinding process.

After performing the chip upper layer removal process, a process of replacing the damaged micro LED chip 240 may be performed.

In the replacement process the damaged micro LED chip 240 can be easily removed from the first coating layer 250 by the gap 251 formed in the lower part of the micro LED chip 240.

When the micro LED chip 240 is replaced, a second jetting process of jetting the second-second coating layer may be performed. A new second-second coating layer 260b may be formed through the second jetting process. Thereafter, the second-second coating layer 260b may be fixed through a second curing process.

When the second-second coating layer 260b is cured, a process of applying the second light scattering layer 270b containing the light scattering agent 271 on the second coating layer 260b may be performed.

Afterwards, a laminating process may be performed after placing the film layer 280b on the light scattering layer 270b.

According to the embodiment, a micro LED module and a micro LED repair process that do not require a separate grinding process in the manufacturing process and repair process may be provided.

In addition, according to the embodiment, an air gap is formed at the bottom of the micro LED chip, making it resistant to thermal shock, and the micro LED chip can be easily removed during the repair process of the micro LED chip.

In addition, according to the example, no bubbles remain due to the coating layer even after the repair process, and visibility can be improved.

In addition, according to the example, the micro LED chip and the first and second coating layers each have different refractive indices, which has the effect of increasing light extraction efficiency.

Additionally, according to the embodiment, the flatness of the micro LED chip module can be improved.

Although the above description focuses on the examples, this is only an example and does not limit the examples, those of ordinary skill in the field to which the embodiment belongs will recognize that various modifications and applications not exemplified above are possible without departing from the essential characteristics of the present embodiment. For example, each element specifically shown in the examples can be modified and implemented. And these variations and differences related to application should be interpreted as being included in the scope of the embodiments set forth in the appended claims.

What is claimed is:

1. A micro LED module for display pixels comprising:
a substrate;
a solder resist layer disposed on the substrate;
an electrode electrically connected to the substrate;
a semiconductor light emitting device connected to the electrode and disposed on the solder resist layer;
a first coating layer disposed on the solder resist layer; and
a second coating layer disposed on the first coating layer,
wherein a top surface of the first coating layer is disposed equal to or lower than a height of a top surface of the semiconductor light emitting device.

2. The micro LED module according to claim 1, wherein a height of the first coating layer is from 80% to 100% of a height of the semiconductor light emitting device.

3. The micro LED module according to claim 1, wherein the first coating layer is formed concavely, and a height of the bottom surface of the first coating layer is formed to be 15% to 75% of the height of the semiconductor light emitting device.

4. The micro LED module according to claim 2, further comprising:
a gap formed between the micro semiconductor light emitting device and the solder resist layer.

5. The micro LED module according to claim 2, further comprising:
an upper chip layer disposed on the second coating layer,
wherein the upper chip layer includes a light scattering layer disposed on the second coating layer, and a film layer disposed on the light scattering layer.

6. The micro LED module according to claim 5,
wherein a refractive index of the first coating layer is 1.48 to 1.60,
wherein a refractive index of the semiconductor light emitting device is 1.7, and
wherein a refractive index of the second coating layer is 1.41 to 1.47.

7. A micro LED module for display pixels comprising:
a substrate;
a solder resist layer disposed on the substrate;
an electrode electrically connected to the substrate;
a semiconductor light emitting device connected to the electrode and disposed on the solder resist layer;
a first coating layer having a sloping surface disposed on the solder resist layer; and
a second coating layer disposed on the sloping surface of the first coating layer and the semiconductor light emitting device.

8. The micro LED module according to claim 7, wherein a top surface of the first coating layer is disposed equal to or lower than a height of a top surface of the semiconductor light emitting device.

9. The micro LED module according to claim 7, wherein the sloping surface of the first coating layer is concave, and a height of the bottom surface of the first coating layer is formed to be 15% to 75% of the height of the semiconductor light emitting device.

10. The micro LED module according to claim 7, further comprising:
a gap formed between the micro semiconductor light emitting device and the solder resist layer.

11. The micro LED module according to claim 7, further comprising:
an upper chip layer disposed on the second coating layer,
wherein the upper chip layer includes a light scattering layer disposed on the second coating layer, and a film layer disposed on the light scattering layer.

12. The micro LED module according to claim 7, wherein a refractive index of the first coating layer is 1.48 to 1.60,
wherein a refractive index of the semiconductor light emitting device is 1.7, and
wherein a refractive index of the second coating layer is 1.41 to 1.47.

13. A display device having a micro module for display pixels according to claim 1.

14. A micro LED repair process for display pixels according to claim 1, comprising:
a removing an upper layer of the semiconductor light emitting device;
replacing the semiconductor light emitting device;
forming a second-second coating layer;
forming a second light scattering layer; and
forming a second film layer.

15. The micro LED repair process according to claim 14, wherein in the step of removing the upper layer of the semiconductor light emitting device comprising:
heating in an infrared oven.

16. The micro LED repair process according to claim 14, wherein the step of forming the second-second coating layer comprising:
jetting the second-second coating layer; and
curing the second-second coating layer.

17. The micro LED repair process according to claim 14, wherein a curing time of the second-second coating layer is shorter than a curing time of the first coating layer.
